(19) United States
(12) Patent Application Publication
(10) Pub. No.: US 2025/0053099 A1
(43) Pub. Date: Feb. 13, 2025

(54) ASYMMETRIC METROLOGY TOOL FOR REFLECTIVE WAVEGUIDE

(71) Applicant: Applied Materials, Inc., Santa Clara, CA (US)

(72) Inventors: Yangyang SUN, San Jose, CA (US); Jinxin FU, Fremont, CA (US); Sihui HE, Santa Clara, CA (US); Ludovic GODET, Sunnyvale, CA (US)

(21) Appl. No.: 18/797,716

(22) Filed: Aug. 8, 2024

Related U.S. Application Data
(60) Provisional application No. 63/531,845, filed on Aug. 10, 2023.

(51) Int. Cl. G03F 7/00

(52) U.S. Cl. CPC G03F 7/706849; G03F 7/706845; G03F 7/706851

(57) ABSTRACT

Embodiments described herein provide an asymmetric optical metrology system for evaluating and inspecting the performance of optical devices, such as augmented reality (AR) waveguide combiners. The system utilizes an asymmetric optical configuration and fly-eye illumination to enhance the detection limit of image sharpness and the accuracy of luminance uniformity. By employing different lenses with various focal lengths, the system increases the sampling rate in the angular space, addressing the challenges of form factor limitations and pixel density inherent in conventional metrology tools. Embodiments described herein offer improved contrast and sharp image details, as well as a compact design, making it suitable for the development, optimization, and quality control of optical devices, such as AR waveguide combiners.

### CROSS-REFERENCE TO RELATED APPLICATIONS

This application claims priority to U.S. Provisional Patent Application Ser. No. 63/531,845 filed on Aug. 10, 2023, which is herein incorporated by reference in its entirety.

### BACKGROUND

### Field

Embodiments of the present disclosure generally relate to the field of optical metrology. More specifically, embodiments described herein provide for a metrology system and a method of optical device metrology.

### Description of the Related Art

Virtual reality is generally considered to be a computer generated simulated environment in which a user has an apparent physical presence. A virtual reality experience can be generated in 3D and viewed with a head-mounted display (HMD), such as glasses or other wearable display devices that have near-eye display panels as lenses to display a virtual reality environment that replaces an actual environment.

Augmented reality, however, enables an experience in which a user can still see through the display lenses of the glasses or other HMD device to view the surrounding environment, yet also see images of virtual objects that are generated for display and appear as part of the environment. Augmented reality can include any type of input, such as audio and haptic inputs, as well as virtual images, graphics, and video that enhances or augments the environment that the user experiences. As an emerging technology, there are many challenges and design constraints with augmented reality.

One such challenge is measuring optical devices for image quality standards. Conventional optical metrology tools often utilize a symmetrical optical configuration, where the same lens system is used for both projection and detection. This design can lead to limitations in form factor and pixel density, which may negatively impact the tool's ability to accurately measure certain performance metrics. Accordingly, what is needed in the art are a metrology system and a method of optical device metrology.

As a result, there is a need for improved optical metrology tools and methods that can overcome these limitations and provide more accurate and reliable measurements of the performance and quality of optical devices, including reflective waveguides used in AR, VR, and other advanced display technologies.

### SUMMARY

In one embodiment, an optical metrology system is provided. The optical metrology system includes a light engine configured to align with an in-coupler of an optical device. The light engine includes a projection lens having a first focal length, the projection lens arranged to receive a test pattern and couple the test pattern into the in-coupler. A reflection detector is configured to align with an out-coupler of the optical device, the reflection detector including a camera lens having a second focal length, the camera lens arranged to receive a reflected test pattern from the out-coupler and project the reflected test pattern to a camera of the reflection detector.

In another embodiment, an optical metrology method is provided. The method includes aligning a light engine with an in-coupler of an optical device, the light engine including a reticle and a projection lens having a first focal length, projecting a test pattern onto the optical device using the light engine, aligning a reflection detector with an out-coupler of the optical device, the reflection detector including a camera lens having a second focal length, receiving a reflected test pattern from the optical device using the reflection detector, and analyzing the reflected test pattern to extract metrology metrics for the optical device.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A is a perspective, frontal view of a substrate according to embodiments described herein.

FIG. 1B is a perspective, frontal view of an optical device according to embodiments described herein.

FIG. 2 is a schematic view of an optical metrology system according to embodiments described herein.

FIG. 3 is a schematic illustration of a light engine and reflection detector of an optical metrology system according to embodiments described herein.

FIG. 4 is a flow diagram of an optical metrology method according to embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

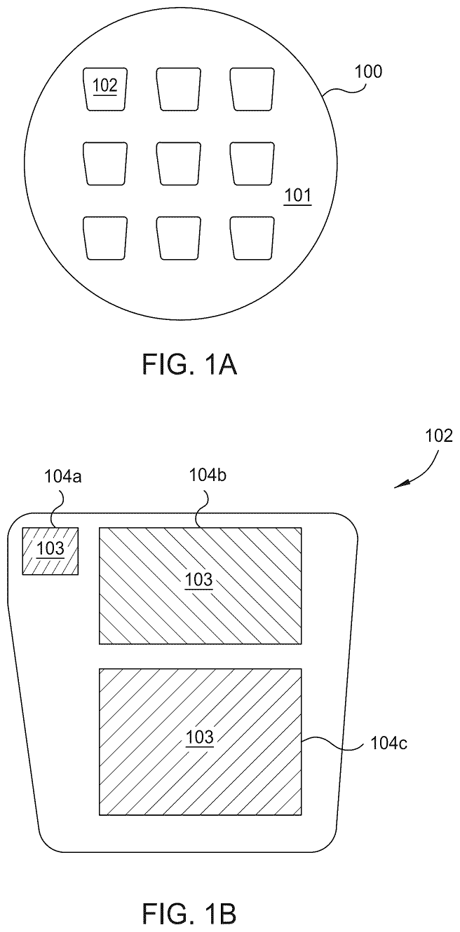

FIG. 1A is a perspective, frontal view of a substrate 100 according to embodiments described herein. The substrate includes a plurality of optical devices 102 disposed on a surface 101 of the substrate 100. The optical devices 102 are waveguide combiners utilized for virtual, augmented, or mixed reality.

The substrate 100 can be any substrate used in the art, and can be either opaque or transparent to a chosen laser wavelength depending on the use of the substrate 100. Additionally, the substrate 100 may be of varying shapes, thicknesses, and diameters. For example, the substrate 100 may have a diameter of about 150 mm to about 300 mm. The substrate 100 may have a circular, rectangular, or square shape. The substrate 100 may have a thickness of between about 300 μm to about 1 mm. Although only nine optical devices 102 are shown on the substrate 100, any number of optical devices 102 may be disposed on the surface 101.

FIG. 1B is a perspective, frontal view of an optical device 102. It is to be understood that the optical devices 102 described herein are exemplary optical devices and the other optical devices may be used with or modified to accomplish aspects of the present disclosure. The optical device 102 includes a plurality of optical device structures 103 disposed on the surface 101 of the substrate 100. The optical device structures 103 may be nanostructures having sub-micron scale dimensions. Regions of the optical device structures 103 correspond to one or more gratings, such as a first grating 104a, a second grating 104b, and a third grating 104c.

In some embodiments, which can be combined with other embodiments described herein, the optical device 102 includes at least a first grating 104a corresponding to an in-coupling grating and a third grating 104c corresponding to an out-coupling grating. In some embodiments, which can be combined with other embodiments described herein, the optical device 102 also includes a second grating 104b corresponding to an intermediate grating. The in-coupling grating and out-coupling grating are also called in-coupler and out-coupler in some embodiments. The optical device structures 103 may be slanted, blazed, binary, or staircase shaped. The optical device structures 103 may have other shapes including, but not limited to, circular, triangular, elliptical, regular polygonal, irregular polygonal, and/or irregular shaped cross-sections.

In operation, the first grating 104a receives incident beams of light (a virtual image) having an intensity from a light source. The incident beams are split by the optical device structures 103 into beams that have all of the intensity of the incident beams in order to direct the virtual image to the second grating (if utilized) 104b or the third grating 104c. In some embodiments, which can be combined with other embodiments described herein, the beams undergo total-internal-reflection (TIR) through the optical device 102 until the beams come in contact with the optical device structures 103 of the second grating 104b. The optical device structures 103 of the second grating 104b diffract the beams to diffracted beams that undergo TIR through the optical device 102 to the optical device structures 103 of the third grating 104c. The optical device structures 103 of the third grating 104c outcouple the diffracted beams to the user's eye to modulate the field of view of the virtual image produced from the light source from the user's perspective and further increase the viewing angle from which the user can view the virtual image. In other embodiments, which can be combined with other embodiments described herein, the beams undergo TIR through the optical device 102 until the beams come in contact with the optical device structures 103 of the third grating 104c and are outcoupled to modulate the field of view of the virtual image produced from the light source.

To ensure that the optical devices 102 meet image quality standards, metrology metrics of the fabricated optical devices 102 may be obtained. The metrology metrics of each optical device 102 are tested to ensure that pre-determined values are achieved. Embodiments of the optical metrology system 200 described herein provide for the ability to obtain multiple metrology metrics with increased throughput. The metrology metrics include one or more of an angular uniformity metric, a contrast metric, a efficiency metric, a color uniformity metric, a modulation transfer function (MTF) metric, a field of view (FOV) metric, a ghost image metric, and an eye box metric.

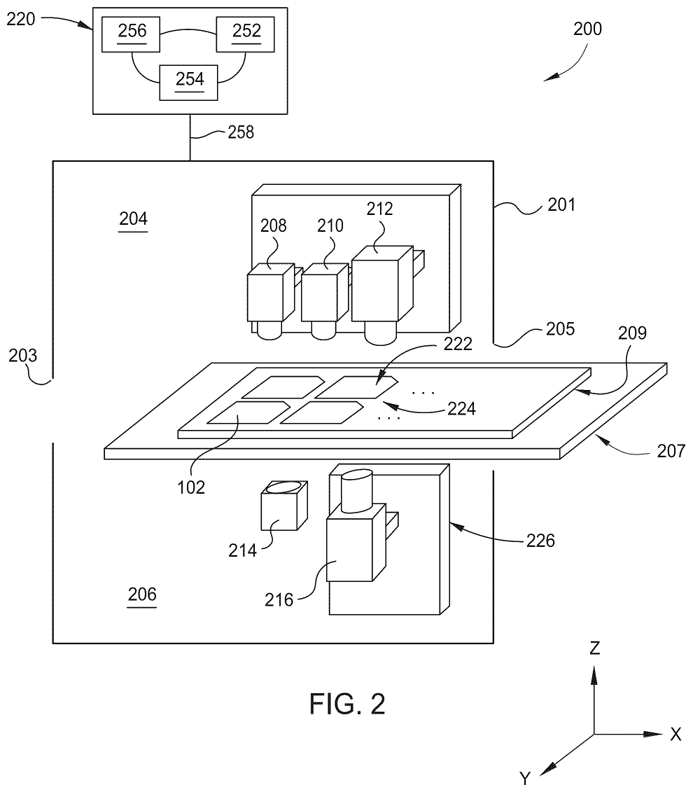

FIG. 2 is a schematic, cross-sectional view of the optical metrology system 200 according to embodiments described herein. The optical metrology system 200 includes a body 201 with a first opening 203 and a second opening 205 to allow a stage 207 to move therethrough. The stage 207 is operable to move in an X-direction, a Y-direction, and a Z-direction in the body 201 of the optical metrology system 200. The stage 207 includes a tray 209 operable to retain the optical devices 102 (as shown herein) or one or more substrates 100.

The optical metrology system 200 is operable to obtain one or more metrology metrics including one or more of the angular uniformity metric, the contrast metric, the efficiency metric, the color uniformity metric, the MTF metric, the FOV metric, the ghost image metric, or the eye box metric. The stage 207 and the tray 209 may be transparent such that the metrology metrics obtained by the optical metrology system 200 are not impacted by the translucence of the stage 207 or the tray 209. The optical metrology system 200 is communicatively coupled to a controller 220. The controller 220 is operable to facilitate operation of the optical metrology system 200.

The controller 220 is coupled to the optical metrology system 200. The controller 220 includes a processor 252, a memory 254, and support circuits 256 that are coupled to one another. The controller 220 is electrically coupled to the optical metrology system 200 via a wire 258. The processor 252 may be one of any form of general purpose microprocessor, or a general purpose central processing unit (CPU), each of which can be used in an industrial setting, such as a programmable logic controller (PLC), supervisory control and data acquisition (SCADA) systems, general purpose graphics processing unit (GPU), or other suitable industrial controller. The memory 254 is non-transitory and may be one or more of readily available memory such as random access memory (RAM), read only memory (ROM), or any other form of digital storage, local or remote. The memory 254 contains instructions, that when executed by the processor 252, facilitates execution of the method 400. The instructions in the memory 254 are in the form of a program product such as a program that implements the method of the present disclosure. The program code of the program product may conform to any one of a number of different programming languages. Illustrative computer-readable storage media include, but are not limited to: (i) non-writable storage media (e.g., read-only memory devices within a computer such as CD-ROM disks readable by a CD-ROM drive, flash memory, ROM chips, or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are examples of the present disclosure.

The optical metrology system 200 includes an upper portion 204 oriented toward a top side of the optical devices 102 and a lower portion 206 oriented toward a bottom side of the optical devices 102. The upper portion 204 of the optical metrology system 200 includes an alignment camera 208, a light engine 210, and a reflection detector 212. The alignment camera 208 is operable to determine a position of the stage 207. The alignment camera 208 is also operable to determine a position of the substrate 100 disposed on the stage 207. The light engine 210 is operable to project light. In some embodiments, which can be combined with other embodiments described herein, the light engine 210 projects a test pattern to the first grating 104a of the optical devices 102. The reflection detector 212 detects light beams out-coupled from a third grating 104c of the optical devices 102. The out-coupled light beams may be emitted from the top side 222 or the bottom side 224 of the optical devices 102. The out-coupled light beams may correspond to the test pattern from the light engine 210. One or more images of the test pattern are detected by the reflection detector 212. The one or more images of the test pattern may be processed with the controller 220 to extract each metrology metric.

The lower portion 206 of the optical metrology system 200 includes a code reader 214 and a transmission detector 216. The code reader 214 and the transmission detector are positioned opposite the alignment camera 208, the light engine 210, and the reflection detector 212 on the other side of the stage 207. The code reader 214 is operable to read a code of an optical device 102, such as a quick response (QR) code or barcode of an optical device 102. The code read by the code reader 214 may include identification information and/or instructions for obtaining the one or more metrology metrics of the optical devices 102. The transmission detector 216 detects the light beams out-coupled from the third grating 104c though the bottom side 224 of the substrate 100. In some embodiments, which can be combined with other embodiments described herein, the transmission detector 216 is coupled to a transmission detector stage 226. The transmission detector stage 226 is operable to move the transmission detector 216 in an X-direction, a Y-direction, and a Z-direction. The transmission detector stage 226 is operable to adjust the position of the transmission detector 216 to enhance the detection of the out-coupled beams projected from the third grating 104c.

In operation, the metrology metrics are obtained by illuminating the first grating 104a of an optical device 102 with the light engine 210. The light engine 210 projects a test pattern to the one or more optical devices 102. The in-coupled light undergoes TIR until the light is coupled out (e.g., reflected or transmitted) of the optical device 102. The test pattern is captured by the reflection detector 212 as one or more images. The one or more images may correspond to red, green, and blue channels. The one or more images may also correspond to one or more different metrology metrics. The one or more images are full-field images.

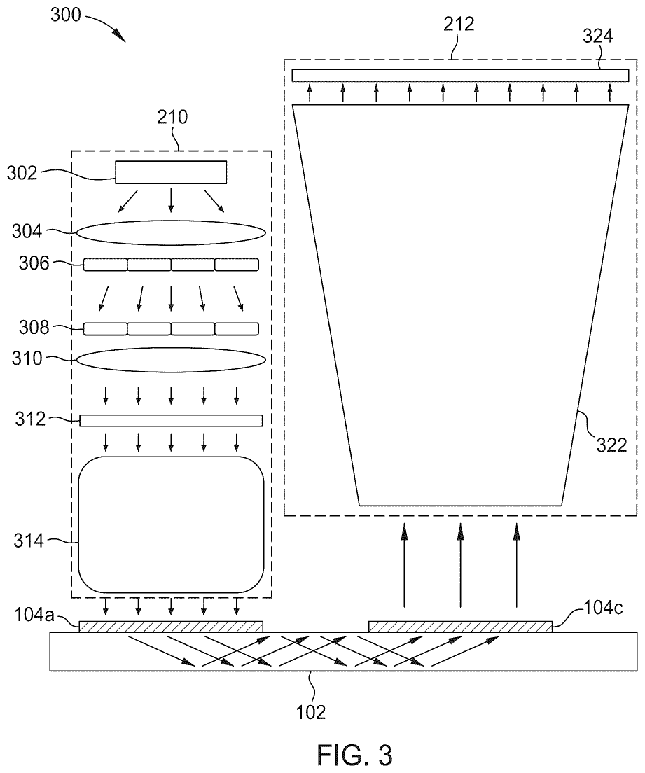

FIG. 3 is a schematic illustration of a light engine and reflection detector of an optical metrology system according to embodiments described herein. The reflection detection module 300 includes the light engine 210 and the reflection detector 212.

The light engine 210 includes several optical components designed to work in conjunction with one another to produce a high-quality, uniform light beam for testing purposes. These components include a light source 302, such as an LED, which emits light. Optionally, the light is directed through a first condenser lens 304. The light is directed through a second condenser lens 310. These lenses help to collimate the light beam, ensuring that it remains focused as it travels through the system. Additionally, the light engine 210 features a first microlens array 306 and a second microlens array 308, which serve to improve the spatial uniformity of the light beam by redistributing its intensity across the beam's cross-section. Finally, the light engine 210 incorporates a test pattern 312 that modulates the light beam according to a specific metrology metric. In some embodiments, the test pattern 312 can be generated from a reticle or microdisplay. The patterned light is then passed through a projection lens 314, which focuses the light onto the optical device under test, such as an AR waveguide combiner. The projection lens includes a focal length of about 10 mm to about 20 mm. For example, the projection lens can include a focal length of about 16 mm.

In the light engine 210, the illumination is provided by a light source 302, such as an LED. Optionally, the light from the light source 302 passes through the first condenser lens 304. The first condenser lens 304 has a focal length ranging from 10 mm to 60 mm. The second condenser lens 310 has a focal length ranging from 10 mm to 60 mm. This lens is responsible for collimating the light beam that originates from the light source 302. A well-collimated light beam provides accurate test pattern projection, and ensures that the light rays are parallel and focused. In some embodiments, which can be combined with other embodiments described herein, the first condenser lens 304 can be removed. The removal of this lens may result in a more compact system.

To further enhance the spatial uniformity, correct the incident angle, the light beam is then modulated by a series of microlens arrays, which includes at least a first microlens array 306 and a second microlens array 308. In operation, the light from the first condenser lens 304 is directed into the first microlens array 306, each individual microlens in the array acts to divide the incident light into multiple smaller beams. This process effectively redistributes the intensity of the light across the beam's cross-section, resulting in improved spatial uniformity. Following this, the light beam proceeds to the second microlens array 308. This array is positioned such that it receives the light from the first microlens array 306 at an oblique angle. The second microlens array 308 are designed to redirect these oblique beams, adjusting their propagation direction to be more parallel to the optical axis of the system. This action corrects the incident angle of the light beam, ensuring that it is optimally aligned for interaction with the subsequent optical components and the device under test.

In some embodiments, the first microlens array 306 and/or 308 has a pitch ranging from 100 μm to 2 mm and an effective focal length (EFL) ranging from 0.2 mm to 2 mm. In this embodiment, the first and the second microlens arrays are identical, and the gap therebetween should be equal to the focal length of the microlenses. In this case, the gap between the first microlens array 306 and the second microlens array 308 is about 0.6 millimeters.

After passing through the second microlens array 308, the light diverges and is recollimated by the second condenser lens 310. The second condenser lens 310 creates a collimated light beam that is directed toward the test pattern 312.

The test pattern 312 serves as the reference image used to evaluate the performance of the AR waveguide combiners. The test pattern 312 can be realized in the form of a reticle or a microdisplay, depending on the desired resolution and application requirements.

In some embodiments, the reticle is a high-resolution patterned mask, which is formed using e-beam, ion-beam, or photolithography techniques. This approach can achieve nanometer scale patterns, allowing for very precise evaluation of the optical devices. Reticle patterns can include checkerboard patterns, line pair patterns, point matrix patterns, or a combination of different patterns, depending on the specific evaluation requirements.

In other embodiments, a microdisplay may be utilized as the test pattern 312. Microdisplays, such as liquid crystal on silicon (LCOS) module, digital light processing (DLP) module, microLED, or organic light-emitting diode (OLED) displays, offer flexibility in terms of pattern generation and dynamic adjustments. However, microdisplays typically have a lower resolution limit compared to reticles, as they are constrained by the pixel size of the display technology.

The test pattern 312 is then projected onto the AR waveguide combiner using a projection lens 314. The test pattern acts as the object plane and is placed at the focal length of the projection lens, resulting in a collimated beam output.

The projection lens 314 is responsible for projecting the test pattern from the reticle or microdisplay onto the first grating 104a of the optical device 102, such as an AR waveguide combiner. By placing the test pattern at the focal length of the projection lens, a collimated beam output is created, which ensures high-quality projection onto the waveguide combiner. The projection lens also ensures that the test pattern is accurately transferred to the optical device, enabling reliable evaluation of its performance.

The distance between the test pattern 312 and the projection lens 314 depends on the working distance. The working distance may not be the same as the focal length, as the mechanical distance might be different due to factors like lens thickness. However, the test pattern should be placed effectively at the focal plane of the projection lens, in this case, ranging from 10 mm to 100 mm.

The reflection detector 212 captures the light reflected from the optical device 102 to evaluate its performance based on the test pattern projected by the light engine 210.

The reflection detector 212 includes a camera lens 322 and a camera 324. The camera lens 322 is designed to have a large field of view (FOV) to capture the entire test pattern reflected from the AR waveguide combiner. This high-resolution lens ensures that the captured image has sufficient detail to evaluate the image quality and luminance uniformity of the combiner accurately.

The camera 324 is typically a high-resolution camera equipped with a charge-coupled device (CCD) or complementary metal-oxide-semiconductor (CMOS) sensor. These sensors are known for their ability to capture images with high fidelity and sensitivity. The camera's resolution and pixel size ultimately determine the metrology system's ability to evaluate the waveguide combiner with the desired level of precision.

In operation, the reflection detector 212 captures the light reflected by the third grating 104c of the optical device 102 after the test pattern has been projected onto it by the light engine 210. The camera lens 322 focuses the reflected light onto the camera 324, and the camera 324 captures the image for further analysis. The camera lens 322 has a focal length of about 20 mm to about 40 mm. For example, the camera lens 322 includes a focal length of 30 mm. By analyzing the captured image, the metrology system can assess the image quality, sharpness, and luminance uniformity of the AR waveguide combiner, allowing for optimization and improvement of its performance.

Embodiments of the disclosed reflection detection module 300 enhances the detection limit of image sharpness and the accuracy of luminance uniformity through its asymmetric design and the use of fly-eye illumination. The asymmetric design involves using different lenses with different focal lengths for the projection lens 314 and the camera lens 322. This configuration allows for higher resolution and better sampling in angular space.

The focal length of the projection lens 314 is less than the focal length of the camera lens 322, which enables it to make use of the high resolution provided by the reticle (or microdisplay) in test pattern 312. Since reticles can achieve resolutions in the sub-micron range, the projection lens can take advantage of this high resolution to create a sharper test pattern. This sharper test pattern is then projected onto the optical device 102, allowing for a more accurate evaluation of its image quality.

The camera lens 322 has a longer focal length, which allows it to capture more details of the projected test pattern reflected from the Optical device 102. With a higher sampling rate, the camera can detect finer details and measure higher frequencies, resulting in a more precise evaluation of the AR waveguide combiner's performance.

The fly-eye illumination in the light engine 210 ensures a high degree of luminance uniformity. This is achieved through the use of the first microlens array 306 and the second microlens array 308. The first microlens array 306 focuses the light onto the second microlens array 308, which corrects any non-normal incident angles. This process guarantees that all the rays are hitting the same point, providing a uniform light distribution across the entire test pattern. The second condenser lens 310 then collimates the light before it interacts with the test pattern 312. This uniform light distribution helps enhance the accuracy of luminance uniformity measurements in the Optical device 102.

In operation, embodiments of the asymmetric metrology tool are designed to correct lateral distortion, enable high-frequency sampling, mitigate form factor limitations, and increase resolution.

Lateral distortion occurs when an image is not uniformly magnified across its entire field of view. In the asymmetric optical system, the use of different lenses with different focal lengths for the projection lens 314 and the camera lens 322 helps to correct some of this distortion. By having a higher magnification on the camera side, any lateral distortion present in the projected test pattern will be reduced when the camera captures the reflected image from the Optical device 102.

High-frequency sampling is achieved by using a longer focal length for the camera lens 322. This results in a larger image magnification, allowing the camera to capture more details and measure higher spatial frequencies. As a result, the metrology tool can detect finer details in the AR waveguide combiner's performance, providing a more accurate evaluation.

The use of a high-resolution reticle (or microdisplay) in the test pattern 312 allows the metrology tool to achieve a high degree of resolution. Reticles, in particular, can achieve resolutions down to sub-micron levels, enabling the projection lens 314 to take advantage of this high resolution to create a sharper test pattern. On the camera side, the longer focal length of the camera lens 322 enables the camera to capture more details of the projected test pattern, further increasing the resolution of the metrology system.

The form factor limitation is addressed by using an asymmetric optical configuration, where the focal length of the projection lens 314 is less than the focal length of the camera lens 322. This enables a smaller lens diameter, allowing both the projector optics and the camera lens to be placed on the same side of the Optical device 102. This compact configuration is particularly beneficial for AR glasses applications, where both the light engine and camera modules are placed on the same side of the device.

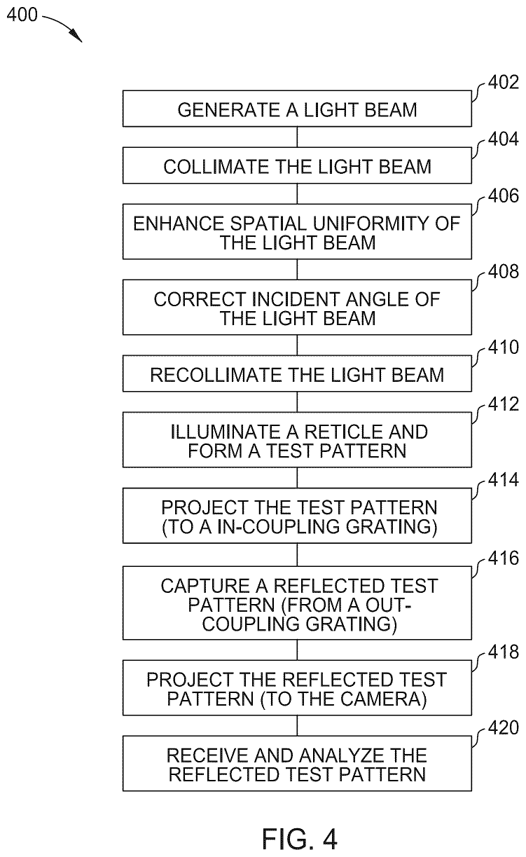

FIG. 4 is a flow diagram of an optical metrology method according to embodiments described herein. To facilitate explanation, the method 400 will be described with reference to the optical metrology system 200 and the reflection detection module 300 shown in FIG. 2 and FIG. 3. The method 400 is operable to be performed in other metrology systems not described herein.

Initially, the optical device is properly positioned and aligned on the stage 207 of the optical metrology system 200. This step sets the stage for the subsequent steps in the metrology process. The positioning ensures that the optical device aligns correctly with both the light engine 210 and the reflection detector 212 of the reflection detection module 300.

The optical device, which could be an AR waveguide combiner or another type of optical device, is typically held in place on a mechanical stage or mount that allows for fine adjustments in position and orientation. This ensures that the test pattern projected from the light engine can be accurately coupled into the in-coupler of the optical device, and that the out-coupled light exiting the out-coupler can be accurately captured by the reflection detector. The light engine 210 and the reflection detector 212 are aligned with respect to the waveguide.

At operation 402, the light engine 210 generates a light beam using the light source 302, and direct the light towards the optical components of the system. The light source 302 can be any suitable type of light source, such as a light-emitting diode (LED), a laser, or a lamp. The light source 302 is typically controlled by a controller (not shown in FIG. 3), which can adjust parameters such as the light intensity and the timing of the light pulses. This allows the metrology tool to adapt to different types of optical devices and testing conditions. In some embodiments, which can be combined with other embodiments described herein, the light engine 210 is operable to be disposed on a rotation stage such that the light engine 210 may be rotated and/or tilted as desired during the method 400.

At operation 404, the light beam is collimated by passing it through the first condenser lens 304 within the light engine 210. Collimation is a technique employed in optical systems to ensure that light rays travel in parallel. This step is pivotal in maintaining the uniformity of the light beam, and consequently, the accuracy of the test pattern projected onto the optical device. The first condenser lens 304, having a focal length around 30 mm, accepts the divergent light beam from the light source 302 and converges it to a point located at its focal plane. This action converts the divergent light beam into a collimated light beam, with the light rays moving in parallel both to each other and to the optical axis.

In certain instances, the design of the metrology tool may exclude the first condenser lens 304, allowing the light beam to interact directly with the first microlens array 306 and the second microlens array 308.

At operation 406, the process involves improving the spatial uniformity of the light beam. This step entails directing the collimated light beam onto a first microlens array 306. The microlens array, also known as a fly-eye lens, can include a multitude of tiny lenses arranged in a uniform array. Each microlens within the array individually focuses the light incident upon it, thereby creating multiple distinct ‘sub-beams’ or ‘beamlets’.

This first microlens array 306 has a pitch ranging from 100 μm to 2 mm and an effective focal length (EFL) ranging from 0.2 mm to 2 mm. For example, the first microlens array 306 can include a pitch ranging from 300 μm and an EFL of 0.6 mm. As the collimated light beam encounters this array, each individual microlens takes a portion of the light and focuses it into a distinct beamlet. The result is a grid-like pattern of beamlets, each correlating with a single microlens in the array.

The primary role of the microlens array in this context is to ensure the spatial uniformity of the light intensity across the entire beam. It achieves this by effectively redistributing the light from the light source 302, thereby migrating the unevenness or ‘hot spots’ in the beam. This uniformity of the light beam is crucial in ensuring an accurate projection of the test pattern onto the optical device.

At operation 408, the aim is to correct the incident angle of the light beam. This is accomplished by directing the beamlets from the first microlens array 306 onto a second microlens array 308. The second microlens array can include a pitch of about 300 μm and an EFL of 0.6 mm. The positioning of the second array can correct the direction of each beamlet, thereby ensuring the beamlets are parallel to the optical axis. This prepares the beamlets for projection onto the reticle or microdisplay.

It's important to note that the correct incident angle of the light beam at this stage significantly affects the quality and accuracy of the projection. An incorrect incident angle could lead to distortions in the projected test pattern, which could, in turn, affect the accuracy of the metrology measurements.

At operation 410, the process involves recollimating the light beam. Following the correction of the incident angle of the light beam at operation 408, the beamlets are then brought back into alignment, or ‘recollimated’, to form a single coherent light beam once again. This can be achieved, for example, by passing the light beam through the second condenser lens 310. The function of this lens is to take the beamlets that were separated and redirected by the first microlens array 306 and the second microlens array 308, and bring the beamlets back together into a unified beam that is parallel to the optical axis of the system. This step is desirable to maintain the focus and parallelism of the light beam as it continues to propagate through the optical system.

At operation 412, the recollimated light beam illuminates the reticle or microdisplay to form the desired test pattern 312. The reticle or microdisplay is a component that modulates the light passing through it to generate a specific pattern. This is done by either blocking or transmitting light in particular regions, depending on the design of the test pattern. The pattern generated by the reticle or microdisplay is typically at a nanometer scale to ensure high precision.

As the light beam passes through the reticle or microdisplay, the pattern interacts with the light beam. This interaction imprints the pattern onto the light beam, turning it into a ‘test pattern’. This test pattern is purposefully designed to effectively test the optical device's performance. It can include various features such as line pairs, checkerboards, or point matrices, which can help to evaluate different performance aspects of the optical device such as its resolution, contrast, and chromatic aberration, among others.

At operation 414, the test pattern is projected onto the first grating 104a of the optical device 102, such as an AR waveguide combiner, using the projection lens 314. The projection lens focuses the light carrying the test pattern and directs it onto the optical device. In the case of an AR waveguide combiner, the light enters the waveguide through the in-coupler.

Once inside the waveguide, the light, carrying the test pattern, travels along the waveguide by total internal reflection. Without being bound by theory, traveling along the waveguide by total internal reflection can keep the light trapped within the waveguide, allowing it to propagate over potentially long distances without substantial loss. The waveguide's properties, such as its physical dimensions, material composition, and internal structures, can modulate the light, thereby influencing one or more of intensity, phase, and polarization due to the interaction with the optical device. The modulated light then exits the waveguide through the third grating 104c and is reflected towards the reflection detector 212.

By projecting the test pattern onto the optical device, the metrology tool sets the stage for assessing the performance of the device. As the test pattern interacts with the optical device, it reveals valuable information about the device's performance characteristics, which will be later captured and analyzed in subsequent operations.

At operations 416 and 418, the camera lens 322 interacts with the reflected test pattern from the optical device. Specifically, in operation 416, the camera lens 322 in the reflection detector picks up the reflected test pattern from the out-coupler of the optical device. This light carries the test pattern and any distortions or alterations the optical device has imposed on it.

The camera lens 322 focuses the reflected light and guides it towards the camera sensor within the reflection detector. The lens has been designed and placed to ensure that it collects as much of the reflected light as possible and that it accurately focuses this light onto the camera sensor. The camera lens's focal length has been chosen to provide a larger field of view and high spatial resolution to capture the details of the test pattern clearly.

In operation 418, the camera lens 322 projects the reflected test pattern onto the camera 324. The optical design of the camera lens can project the test pattern onto the camera sensor accurately, preserving the spatial relationships in the pattern and any distortions imposed by the optical device.

At operation 420, the camera 324 receives and records the reflected test pattern. The camera 324, equipped with either a CCD or CMOS sensor, captures an image of the reflected light that carries the test pattern. The image is a replication of the light that has interacted with the optical device, having undergone transformations due to the properties of the optical device itself.

The recorded image data is then transferred to the controller 220 for processing and analysis. The recorded image data is processed and analyzed, often using advanced image processing algorithms and techniques. This process involves comparing the captured image of the reflected test pattern against the original pattern to determine any discrepancies. By analyzing these differences, the system can deduce the optical performance and characteristics of the device under test.

In addition to the spatial properties of the image, the camera 324 may also record other properties of the reflected light, such as its intensity or color, which can provide additional information about the optical device's performance. The system can use these data to calculate luminance uniformity, distortion, image sharpness, and other relevant metrology metrics that define the quality of the optical device. The results of the analysis are reported, providing valuable feedback for the development, optimization, and quality control of the optical device. This information can be used to provide a thorough and accurate evaluation of the optical device's performance.

While the foregoing is directed to examples of the present disclosure, other and further examples of the disclosure may be devised without departing from the basic scope thereof, and the scope thereof is determined by the claims that follow.

What is claimed is:

1. A optical metrology system, comprising:
a light engine comprising:
a light source disposed over one or more microlens arrays;
one or more condenser lens disposed under the one or more microlens arrays, wherein the one or more condenser lens are disposed over a reticle; and
a projection lens, having a first focal length, disposed under the reticle, wherein the projection lens is configured to align with an in-coupler of an optical device; and
a reflection detector comprising:
a camera lens, having a second focal length, wherein the camera lens is configured to align with an out-coupler of the optical device; and
a camera disposed over the camera lens, the camera configured to receive light from the camera lens,
wherein the first focal length and the second focal length are different.

2. The optical metrology system of claim 1, wherein the first focal length is less than the second focal length.

3. The optical metrology system of claim 1, wherein the first focal length is about 10 mm to about 20 mm, and the second focal length is about 20 mm to about 40 mm.

4. The optical metrology system of claim 1, wherein the light engine comprises a first condenser lens and a second condenser lens.

5. The optical metrology system of claim 4, wherein the first condenser lens is disposed over the one or more microlens arrays, and the second condenser lens is disposed under the one or more microlens arrays.

6. The optical metrology system of claim 4, wherein the first condenser lens comprises a third focal length of about 10 mm to about 60 mm, and the second condenser lens comprises a fourth focal length of about 10 mm to about 60 mm.

7. The optical metrology system of claim 1, wherein one or more microlens arrays comprise a first microlens array and a second microlens array.

8. The optical metrology system of claim 7, wherein the first microlens array comprises a fifth focal length of about 0.2 mm to about 2 mm, and the second microlens array comprises a sixth focal length of 0.2 mm to 2 mm.

9. The optical metrology system of claim 1, further comprising a controller communicatively coupled to the light engine and the reflection detector, wherein the controller is configured to process a test pattern from the reflection detector.

10. A optical metrology system, comprising:
a light engine comprising:
a light source disposed over one or more microlens arrays;
one or more condenser lens disposed under the one or more microlens arrays, wherein the one or more condenser lens are disposed over a reticle; and
a projection lens, having a first focal length, disposed under the reticle, wherein the projection lens is configured to align with an in-coupler of an optical device; and
a reflection detector comprising:
a camera lens, having a second focal length, wherein the camera lens is configured to align with an out-coupler of the optical device; and
a camera disposed over the camera lens, the camera configured to receive light from the camera lens,
wherein the first focal length is about 10 mm to about 20 mm, and the second focal length is about 20 mm to about 40 mm.

11. The optical metrology system of claim 10, wherein the light engine comprises a first condenser lens and a second condenser lens.

12. The optical metrology system of claim 11, wherein the first condenser lens is disposed over the one or more microlens arrays, and the second condenser lens is disposed under the one or more microlens arrays.

13. The optical metrology system of claim 12, wherein the first condenser lens comprises a third focal length of about 10 mm to about 60 mm, and the second condenser lens comprises a fourth focal length of about 10 mm to about 60 mm.

14. The optical metrology system of claim 10, wherein one or more microlens arrays comprise a first microlens array and a second microlens array.

15. The optical metrology system of claim 14, wherein the first microlens array comprises a fifth focal length of about 0.2 mm to about 2 mm, and the second microlens array comprises a sixth focal length of 0.2 mm to 2 mm.

16. The optical metrology system of claim 10, further comprising a controller communicatively coupled to the light engine and the reflection detector, wherein the controller is configured to process a test pattern from the reflection detector.

17. A method, comprising:
aligning a light engine with an in-coupler of an optical device, the light engine comprising one or more microlens arrays, one or more condenser lens disposed under the one or more microlens arrays, a reticle disposed under the one or more condensers, and a projection lens disposed under the reticle, wherein the projection lens comprises a first focal length;
projecting a test pattern onto the optical device using the light engine;
aligning a reflection detector with an out-coupler of the optical device, the reflection detector comprising a camera lens and a camera disposed over the camera lens, wherein the camera lens comprises a second focal length, wherein the first focal length is less than the second focal length;
receiving a reflected test pattern from the optical device using the reflection detector; and
determining one or more metrology metrics for the optical device based on the reflected test pattern.

18. The method of claim 17, wherein the one or more metrology metrics comprise image sharpness, luminance uniformity, and distortion.

19. The method of claim 17, wherein projecting the test pattern comprises modulating the test pattern based on one or more optical device properties.

20. The method of claim 19, wherein the one or more optical device properties comprises physical dimensions, material composition, and internal structures.
